(19) United States
(12) Patent Application Publication
(10) Pub. No.: US 2007/0069396 A1
(43) Pub. Date: Mar. 29, 2007

(54) Semiconductor package, method of manufacturing the same, stacked semiconductor package including the same and method of manufacturing the stacked semiconductor package

(75) Inventors: Hyung-Gil Baek, Suwon-si (KR); Sang-Wook Park, Seongnam-si (KR); Joong-Hyun Baek, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/525,903

(22) Filed: Sep. 25, 2006

(30) Foreign Application Priority Data
Sep. 29, 2005 (KR) 10-2005-0090921

(51) Int. Cl. H01L 29/40; H01L 21/00

(52) U.S. Cl. 257/782; 257/783; 438/118; 257/E23.003

(57) ABSTRACT

Example embodiments relate to a semiconductor package, a method of manufacturing the semiconductor package, a stacked semiconductor package including the semiconductor package, and a method of manufacturing the stacked semiconductor package. Other example embodiments relate to a semiconductor package having a structure that allows at least two packages to be stacked, a method of manufacturing the semiconductor package, a stacked semiconductor package including the semiconductor package, and a method of manufacturing the stacked semiconductor package. A semiconductor package may include a first circuit substrate having signal patterns that may be formed on an outer face of the first circuit substrate, a second circuit substrate facing an inner face of the first circuit substrate, a semiconductor chip inserted between the first and second circuit substrates and electrically connected to the signal patterns, and a connection member for electrically connecting the first circuit substrate to the second circuit substrate. N (where N is an integer ≧2) semiconductor packages may be stacked to form a stacked semiconductor package.

### PRIORITY STATEMENT

This application claims priority under 35 USC § 119 to Korean Patent Application No. 2005-90921, filed on Sep. 29, 2005, in the Korean Intellectual Property Office (KIPO), the entire contents of which are herein incorporated by reference.

### BACKGROUND

1. Field

Example embodiments relate to a semiconductor package, a method of manufacturing the semiconductor package, a stacked semiconductor package including the semiconductor package, and a method of manufacturing the stacked semiconductor package. Other example embodiments relate to a semiconductor package having a structure that allows at least two packages to be stacked, a method of manufacturing the semiconductor package, a stacked semiconductor package including the semiconductor package, and a method of manufacturing the stacked semiconductor package.

2. Description of the Related Art

A semiconductor device may be manufactured by forming an integrated circuit on a silicon substrate to manufacture a semiconductor chip, an electrical die sorting (EDS) process for testing and sorting the semiconductor chip, and a packaging process for protecting the semiconductor chip. In order to improve the integration degree of the semiconductor device, a chip scale package (CSP) and/or a stacked package have been developed. A conventional stacked package may include two vertically stacked semiconductor packages. Each of the semiconductor packages may include a semiconductor chip and a substrate on which the semiconductor chip is mounted. The conventional stacked package may have a shape in which the substrate and the semiconductor chip are alternately arranged. The substrates may be electrically connected to each other using solder balls.

Because the semiconductor chip of the conventional stacked package has a thermal expansion coefficient different from that of the substrate, the conventional stacked package may be warped. Also, because the conventional stacked package exposes portions of the semiconductor chip, the conventional stacked package may be damaged due to external impact. Furthermore, because the conventional stacked package has two semiconductor packages with different structures, a process for manufacturing the conventional stacked package may be complicated.

### SUMMARY

Example embodiments provide a semiconductor package that is not damaged due to warpage and/or an external impact. Example embodiments also provide a method of manufacturing the semiconductor package. Example embodiments still also provide a stacked semiconductor package in which the above-mentioned semiconductor packages are stacked and a method of manufacturing the above-mentioned stacked semiconductor package.

A semiconductor package in accordance with example embodiments may include a first circuit substrate having signal patterns that may be formed on an outer face of the first circuit substrate, a second circuit substrate facing an inner face of the first circuit substrate, a semiconductor chip inserted between the first and second circuit substrates and electrically connected to the signal patterns, and a connection member for electrically connecting the first circuit substrate to the second circuit substrate. The first and second circuit substrates may have a first thermal expansion coefficient, and the semiconductor chip may have a second thermal expansion coefficient lower than the first thermal expansion coefficient. The semiconductor chip may have a first area, and the first and second circuit substrates may have a second area larger than the first area. The first circuit substrate may have a first aperture for exposing bonding pads of the semiconductor chip.

The first circuit substrate may further include first conductive members electrically connected to the signal patterns. The outermost of the conductive members may be partially arranged at an outside of an edge of the semiconductor chip. The connection member may include a spherical solder ball for electrically connecting the first and second circuit substrates to each other. The second circuit substrate may have a second aperture corresponding to the connection member. The second circuit substrate may further include a connection pattern in the second aperture.

A semiconductor package may further include conductive wires for electrically connecting the bonding pads to the signal patterns, an insulation member for covering the conductive wires to insulate the conductive wires, a protection member inserted between edge portions of the first and second circuit substrates to protect the semiconductor chip and adhesive members inserted between the first circuit substrate and the semiconductor chip, and between the semiconductor chip and the second circuit substrate to attach the first and second circuit substrates to the semiconductor chip.

In a method of manufacturing a semiconductor package in accordance with other example embodiments, a first circuit substrate having signal patterns that may be formed on an outer face of the first circuit substrate, and a second circuit substrate facing an inner face of the first circuit substrate may be prepared. A connection member may be positioned between the first and second circuit substrates. A semiconductor chip may be inserted between the first and second circuit substrates and may then be electrically connected to the signal patterns. Preparing the first circuit substrate may include forming a first aperture through the first circuit substrate to expose bonding pads of the semiconductor chip, electrically connecting the bonding pads to the signal patterns using conductive wires and insulating the conductive wires using an insulation member.

The method of manufacturing a semiconductor package may further include forming a second aperture through the second circuit substrate to expose the connection member, filling the second aperture with a solder paste, melting the solder paste to electrically connect the solder paste to the connection member and filling a space defined by the first and second circuit substrates and a side face of the semiconductor chip with a melted resin, hardening the melted resin to form a protection member and mounting conductive balls on the signal patterns.

A stacked semiconductor package in accordance with still other example embodiments may include N (where N is an integer ≧2) semiconductor packages according to example embodiments. The first circuit substrate of the (N−1)th semiconductor package may face the second circuit substrate of the Nth semiconductor package. The (N−1)th and Nth semiconductor chips may have bonding pads electrically connected to the (N−1)th and Nth signal patterns. An adhesive member may be inserted between the first circuit substrate of the (N−1)th semiconductor package and the second circuit substrate of the Nth semiconductor package. The first circuit substrate of the (N−1)th semiconductor package and the second circuit substrate of the Nth semiconductor package may include apertures to expose the (N−1)th and Nth connection members, respectively and connection patterns may be formed in the apertures to electrically connect the (N−1)th and Nth connection members to each other.

In a method of manufacturing a stacked semiconductor package in accordance with still other example embodiments, N (where N is an integer ≧2) semiconductor packages according to example embodiments may be prepared and the Nth semiconductor package on the (N−1)th semiconductor package may be stacked to electrically connect the (N−1)th and Nth connection members to each other. The first circuit substrate of the (N−1)th semiconductor package may face the second circuit substrate of the Nth semiconductor package. The (N−1)th and Nth semiconductor chips may have bonding pads electrically connected to the (N−1)th and Nth signal patterns.

### BRIEF DESCRIPTION OF THE DRAWINGS

Example embodiments will be more clearly understood from the following detailed description taken in conjunction with the accompanying drawings. FIGS. 1-11 represent non-limiting, example embodiments as described herein.

FIG. 1 is a diagram illustrating a semiconductor package in accordance with example embodiments;

FIG. 2 is a diagram illustrating a conductive wire electrically connected to a semiconductor chip and an insulation member in FIG. 1;

FIG. 3 is a diagram illustrating a conductive member on signal patterns in FIG. 1;

FIG. 4 is a diagram illustrating a conductive pattern on the semiconductor package in FIG. 1;

FIG. 5 is a flow chart illustrating a method of manufacturing the semiconductor package in FIG. 1;

FIG. 6 is a diagram illustrating first and second circuit substrates of a semiconductor package in FIG. 1;

FIG. 7 is a diagram illustrating a semiconductor chip and a connection member inserted between the first and second circuit substrates in FIG. 6;

FIG. 8 is a diagram illustrating conductive wires and connection patterns on the semiconductor package in FIG. 7;

FIG. 9 is a diagram illustrating a conductive member electrically connected to signal patterns in FIG. 8;

FIG. 10 is a diagram illustrating a stacked semiconductor package in accordance with still other example embodiments; and

FIG. 11 is a diagram illustrating a method of manufacturing the stacked semiconductor package in FIG. 10.

### DESCRIPTION OF EXAMPLE EMBODIMENTS

Example embodiments are described more fully hereinafter with reference to the accompanying drawings, in which example embodiments are shown. Example embodiments may, however, be embodied in many different forms and should not be construed as limited to the embodiments set forth herein. Rather, these embodiments are provided so that this disclosure will be thorough and complete, and will fully convey the scope of example embodiments to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. A first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. The exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. The regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Example embodiments relate to a semiconductor package, a method of manufacturing the semiconductor package, a stacked semiconductor package including the semiconductor package, and a method of manufacturing the stacked semiconductor package. Other example embodiments relate to a semiconductor package having a structure that allows at least two packages to be stacked, a method of manufacturing the semiconductor package, a stacked semiconductor package including the semiconductor package, and a method of manufacturing the stacked semiconductor package.

Semiconductor Package

FIG. 1 is a diagram illustrating a semiconductor package in accordance with example embodiments. Referring to FIG. 1, a semiconductor package 100 of example embodiments may include a first circuit substrate 10, a second circuit substrate 20, a semiconductor chip 30 and a connection member 40. The first circuit substrate 10 may have a first face 11 and a second face 12 opposite to the first face 11. Signal patterns 13 for inputting/outputting a signal into/from the first circuit substrate 10 may be formed on the first face 11. The first circuit substrate 10 may include a relatively thin printed circuit board (PCB).

The second circuit substrate 20 may face the first circuit substrate 10. The second circuit substrate 20 may have a third face 21 and a fourth face 22 opposite to the third face 21. In example embodiments, the third face 21 of the second circuit substrate 20 may face the first face 11 of the first circuit substrate 10. The second circuit substrate 20 may include a relatively thin PCB. The semiconductor chip 30 may be inserted between the first circuit substrate 10 and the second circuit substrate 20. The semiconductor chip 30 may be electrically connected to the signal patterns 13 to receive the signals from the signal patterns 13 and/or output the signals through the signal patterns 13. In example embodiments, a first adhesive member 42 may be inserted between the first circuit substrate 10 and the semiconductor chip 30. A second adhesive member 44 may be inserted between the second circuit substrate 20 and the semiconductor chip 30.

The connection member 40 may be inserted between the first face 11 of the first circuit substrate 10 and the third face 21 of the second circuit substrate 20 to electrically connect the first circuit substrate 10 to the second circuit substrate 20. In example embodiments, the first circuit substrate 10 and the second circuit substrate 20 may absorb external forces to reduce damage to the semiconductor chip 30.

The first circuit substrate 10 and the second circuit substrate 20 may have a first thermal expansion coefficient. The semiconductor chip 30 may have a second thermal expansion coefficient lower than the first thermal expansion coefficient. Because a difference between the first and second coefficients of thermal expansion is compensated with the first and second circuit substrates 10 and 20, the semiconductor chip 30 inserted between the first and second circuit substrates 10 and 20 may not be warped. The semiconductor chip 30 may have a first area on a plan view. The first and second circuit substrates 10 and 20 may have a second area larger than the first area on a plan view. The semiconductor chip 30 having the first area may be inserted between central portions of the first and second circuit substrates 10 and 20 having the second area. The connection member 40 may be inserted between edge portions of the first and second circuit substrates 10 and 20 that are not overlapped with the semiconductor chip 30.

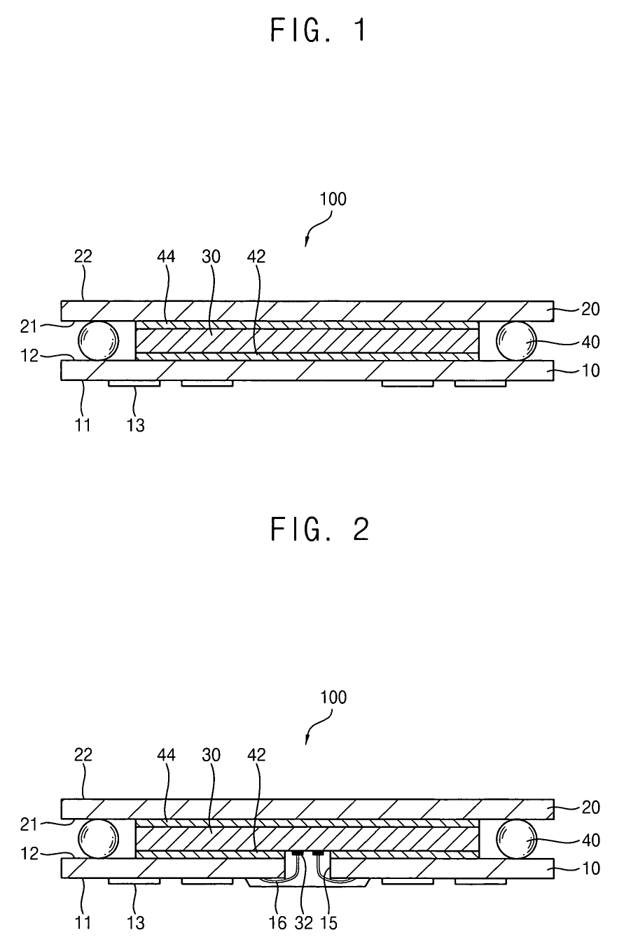

FIG. 2 is a diagram illustrating a conductive wire electrically connected to a semiconductor chip and an insulation member in FIG. 1. Referring to FIG. 2, bonding pads 32, through which the signals are transmitted, may be arranged on the semiconductor chip 30. In example embodiments, the bonding pads 32 may be formed on a lower face of the semiconductor chip 30 facing the second face 12 of the first circuit substrate 10. The bonding pads 32 may be arranged on a central lower face of the semiconductor chip 30.

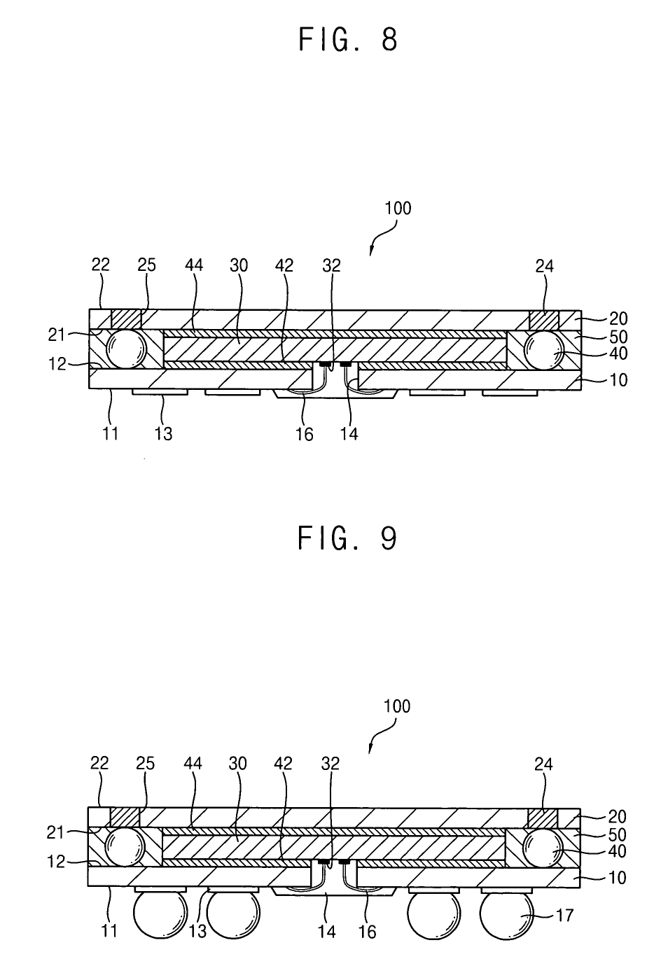

The first circuit substrate 10 may have a first aperture 15 for exposing the bonding pads 32 (shown in FIG. 8) of the semiconductor chip 30. The first aperture 15 may have an area suitable for exposing the bonding pads 32 (shown in FIG. 8) of the semiconductor chip 30. The bonding pads 32 (shown in FIG. 8) of the semiconductor chip 30, exposed through the first aperture 15, may be electrically connected to the signal patterns 13 of the first circuit substrate 10 through conductive wires 16. To insulate the conductive wires 16 for electrically connecting the bonding pads 32 to the signal patterns 13, the conductive wires 16 may be encapsulated with an insulation member (e.g., an epoxy resin).

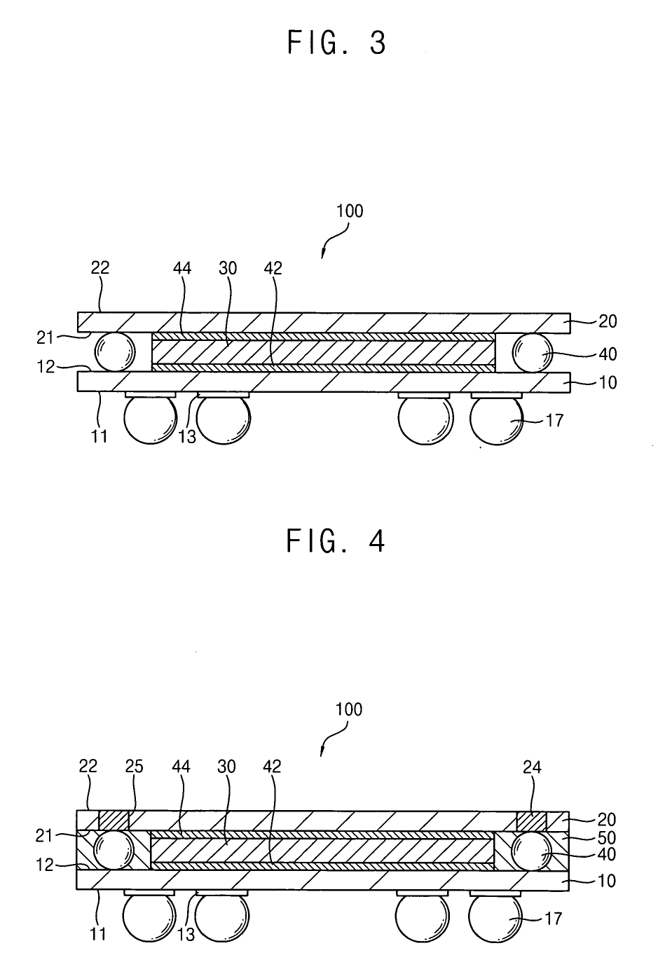

FIG. 3 is a diagram illustrating a conductive member on signal patterns in FIG. 1. Referring to FIG. 3, spherical conductive members 17 may be mounted on the signal patterns 13 of the first circuit substrate 10. In example embodiments, the spherical conductive members 17 may include solder balls. The outermost of the spherical conductive members 17 may have a fan-out structure, which means that the outermost of the spherical conductive members 17 may be partially overlapped with edges of the semiconductor chip 30. Alternatively, the spherical conductive members 17 may not be overlapped with the edges of the semiconductor chip 30.

FIG. 4 is a diagram illustrating a conductive pattern on the semiconductor package in FIG. 1. Referring to FIG. 4, conductive connection patterns 24 may be provided to the second circuit substrate 20 of the semiconductor package 100. In example embodiments, the conductive connection patterns 24 may function as a terminal for allowing the semiconductor packages 100 to be stacked. To form the conductive connection patterns 24, second apertures 25 may be formed through edge portions of the second circuit substrate 20 corresponding to the connection members 40. The second apertures 25 may be filled with the conductive connection patterns 24. The connection members 40, electrically connected to the first circuit substrate 20, may make direct electrical contact with the connection patterns 24 in the second circuit substrate 20. In example embodiments, the connection patterns 24 may include a solder formed by melting a solder paste.

A protection member 50 may be formed between the edge portions of the first and second circuit substrates 10 and 20. The protection member 50 may reduce damage to side faces of the semiconductor chip 30 and the connection members 40. The protection member 50 may retard or prevent an interval between the edge portions of the first and second circuit substrates 10 and 20 from being narrowed or widened. The protection member 50 may include an epoxy resin.

Method of Manufacturinq a Semiconductor Package

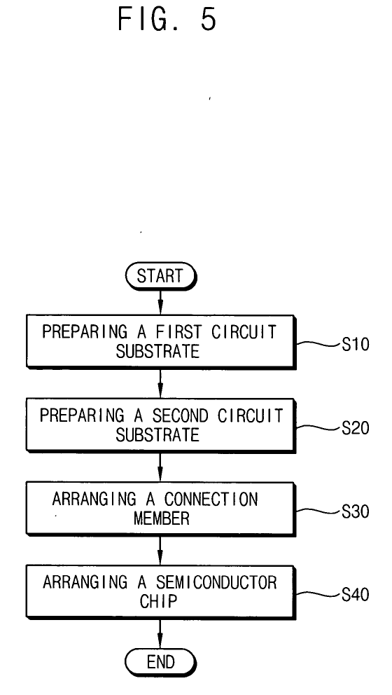

FIG. 5 is a flow chart illustrating a method of manufacturing the semiconductor package in FIG. 1. Referring to FIG. 5, in S10, the first circuit substrate, having the signal patterns, may be prepared. In S20, the second circuit substrate, facing the first circuit substrate, may then be prepared. In S30, the connection member may be inserted between the first and second circuit substrates. In S40, the semiconductor chip electrically connected to the signal patterns may be arranged between the first and second circuit substrates.

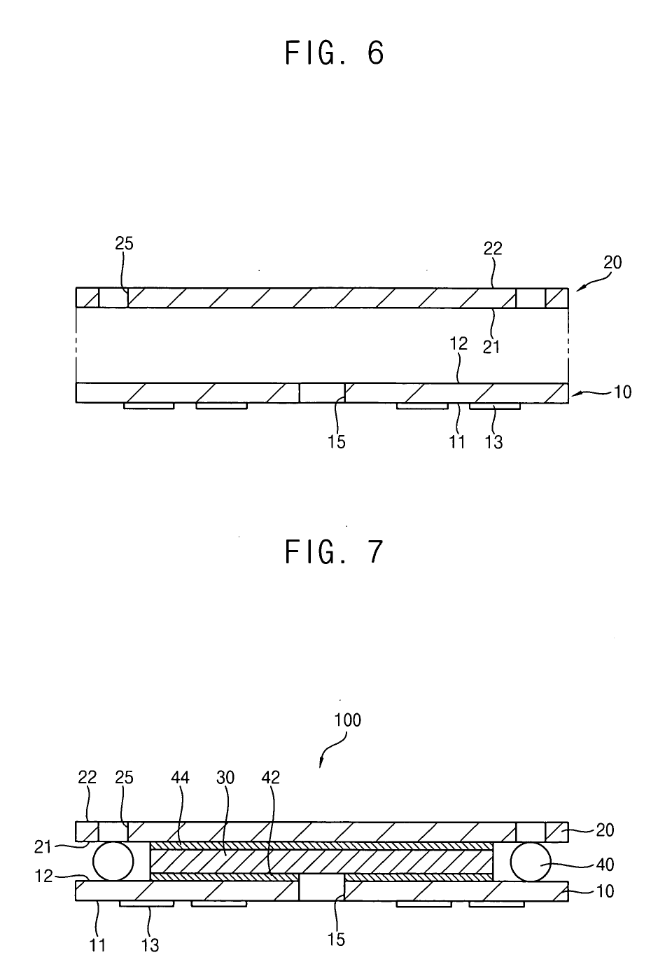

FIG. 6 is a diagram illustrating first and second circuit substrates of a semiconductor package in FIG. 1. Referring to FIGS. 5 and 6, in S10, the first circuit substrate 10 may be prepared. In example embodiments, the first circuit substrate 10 may include a thin printed circuit board (PCB) having the first face 11 and the second face 12. The signal patterns 13 may be formed on the first face 11 of the first circuit substrate 10. The first aperture 15 may then be formed through the central portion of the first circuit substrate 10.

In S20, the second circuit substrate 20 may be prepared. In example embodiments, the second circuit substrate 20 may include a PCB having the third face 21 and the fourth face 22. The third face 21 of the second circuit substrate 20 may face the first face 11 of the first circuit substrate 10. The second apertures 25 may then be formed through the edge portions of the second circuit substrate 20.

FIG. 7 is a diagram illustrating a semiconductor chip and a connection member inserted between the first and second circuit substrates in FIG. 6. Referring to FIGS. 5 and 7, the semiconductor chip 30 and the connection members 40 may be arranged between the first and second circuit substrates 10 and 20. The semiconductor chip 30 may be placed on the central portion of first circuit substrate 10. The bonding pads 32 (shown in FIG. 8) of the semiconductor chip 30 may be exposed through the first aperture 15 in the first circuit substrate 10. In example embodiments, the first adhesive member 42 may be inserted between the first face 11 of the first circuit substrate 10 and the semiconductor chip 30.

The connection members 40 may be formed on the edge portions of the first circuit substrate 10. The connection members 40 may be spaced apart from the semiconductor chip 30. The connection members 40 may include solder balls. Positions of the connection members 40 may correspond to those of the second apertures 25 formed through the second circuit substrate 20. The third face 21 of the second circuit substrate 20 may be placed on the semiconductor chip 30. The second circuit substrate 20 and the semiconductor chip 30 may be attached to each other using the second adhesive member 44 inserted between the semiconductor chip 30 and the third face 21 of the second circuit substrate 20.

FIG. 8 is a diagram illustrating conductive wires and connection patterns on the semiconductor package in FIG. 7. Referring to FIG. 8, after the first circuit substrate 10, the semiconductor chip 30 and the second circuit substrate 20 may be assembled and the bonding pads 32 of the semiconductor chip 30 may be electrically connected to the signal patterns 13 of the first circuit substrate 10 through the conductive wires 16. The conductive wires 16 may be encapsulated with the insulation member 14 including an epoxy resin so that the conductive wires 16 are insulated.

The second apertures 25 of the second circuit substrate 20 may be filled with the solder paste including relatively small solder powders by a silk screen-printing process. The solder paste may be melted in an infrared furnace to form the connection patterns 24, which is electrically connected to the connection members 40, in the second apertures 25. The connection members 40 may be electrically and physically connected to the second circuit substrate 20 through the connection patterns 24. After the connection members 40 are electrically connected to the connection patterns 24, a space between the first and second circuit substrates 10 and 20 may be filled with a fluidic epoxy resin to form the protection member 50 between the first and second circuit substrates 10 and 20. The protection member 50 may fix the connection members 40. The protection member 50 may protect the side faces of the semiconductor chip 30 from an external impact.

FIG. 9 is a diagram illustrating a conductive member electrically connected to signal patterns in FIG. 8. Referring to FIG. 9, the conductive members 17 may be mounted on the signal patterns 13 of the first circuit substrate 10, respectively. In example embodiments, the conductive members 17 may include a solder ball having a relatively low melting point.

Stacked Semiconductor Package

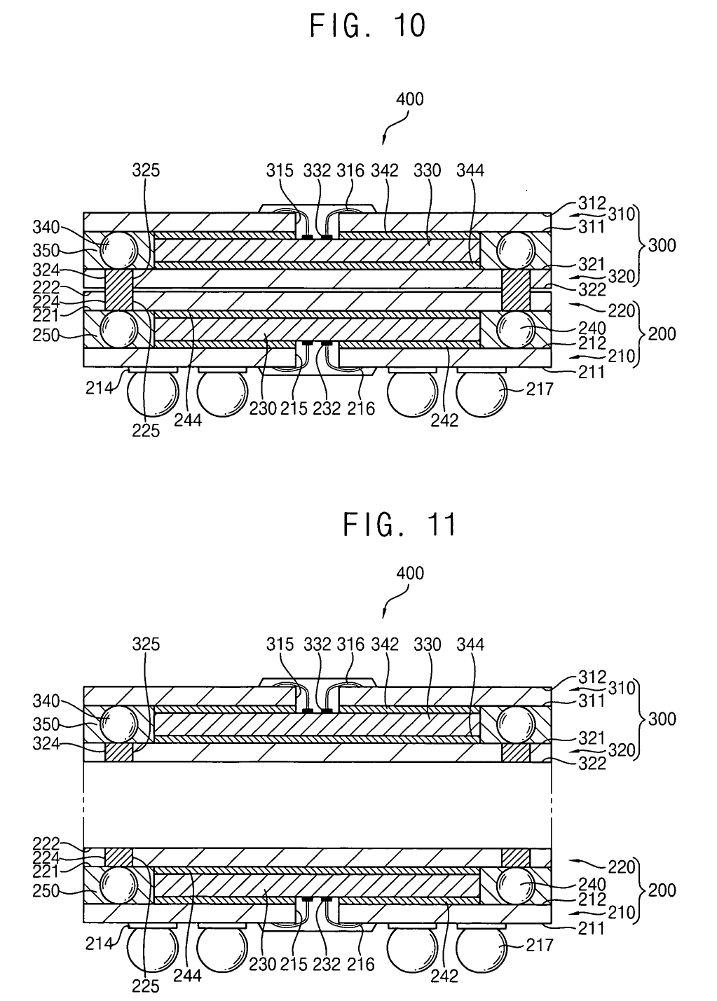

FIG. 10 is a diagram illustrating a stacked semiconductor package in accordance with still other example embodiments. Referring to FIG. 10, a stacked semiconductor package 400 of example embodiments may include a (N−1)th (wherein N is an integer ≧2) semiconductor package 200 and a Nth semiconductor package 300. The (N−1)th semiconductor package 200 may include a first circuit substrate 210, a second circuit substrate 220, a (N−1)th semiconductor chip 230 and a (N−1)th connection member 240.

In example embodiments, the first circuit substrate 210 may have a first face 211 and a second face 212 opposite to the first face 211. (N−1)th signal patterns 214 for inputting/outputting signal into/from the first circuit substrate 210 may be formed on the first face 211. The first circuit substrate 210 may include a relatively thin printed circuit board (PCB). The second circuit substrate 220 may face the first circuit substrate 210. The second circuit substrate 220 may have a third face 221 and a fourth face 222 opposite to the third face 221. In example embodiments, the third face 221 of the second circuit substrate 220 may face the first face 211 of the first circuit substrate 210. The second circuit substrate 220 may include a relatively thin PCB.

The (N−1)th semiconductor chip 230 may be inserted between the first circuit substrate 210 and the second circuit substrate 220. The (N−1)th semiconductor chip 230 may be electrically connected to the (N−1)th signal patterns 214 to receive the signals from the (N−1)th signal patterns 214 or output the signals through the (N−1)th signal patterns 214. In example embodiments, a (N−1)th adhesive member 242 may be inserted between the first circuit substrate 210 and the (N−1)th semiconductor chip 230. A Nth adhesive member 244 may be inserted between the second circuit substrate 220 and the (N−1)th semiconductor chip 230.

The (N−1)th connection members 240 may be inserted between the first face 211 of the first circuit substrate 210 and the third face 221 of the second circuit substrate 220 to electrically connect the first circuit substrate 210 to the second circuit substrate 220. In example embodiments, the first circuit substrate 210 and the second circuit substrate 220 may absorb external forces to reduce damage to the (N−1)th semiconductor chip 230. The first circuit substrate 210 and the second circuit substrate 220 may have a first thermal expansion coefficient. The (N−1)th semiconductor chip 230 may have a second thermal expansion coefficient lower than the first thermal expansion coefficient. Because a difference between the first and second coefficients of thermal expansion is compensated with the first and second circuit substrates 210 and 220, the (N−1)th semiconductor chip 230, inserted between the first and second circuit substrates 210 and 220, may not be warped.

The (N−1)th semiconductor chip 230 may have a first area on a plan view. The first and second circuit substrates 210 and 220 may have a second area larger than the first area on a plan view. The (N−1)th semiconductor chip 230 having the first area may be inserted between central portions of the first and second circuit substrates 210 and 220 having the second area. The (N−1)th connection member 240 may be inserted between edge portions of the first and second circuit substrates 210 and 220 that are not overlapped with the (N−1)th semiconductor chip 230.

(N−1)th bonding pads 232 through which the signals are transmitted may be arranged on the (N−1)th semiconductor chip 230. In example embodiments, the (N−1)th bonding pads 232 may be formed on a lower face of the (N−1)th semiconductor chip 230 facing the second face 212 of the first circuit substrate 210. The (N−1)th bonding pads 232 may be arranged on a central lower face of the (N−1)th semiconductor chip 230.

The first circuit substrate 210 may have a first aperture 215 for exposing the (N−1)th bonding pads 232 on the (N−1)th semiconductor chip 230. The first aperture 215 may have an area suitable for exposing the (N−1)th bonding pads 232 on the (N−1)th semiconductor chip 230. The (N−1)th bonding pads 232 on the (N−1)th semiconductor chip 230, exposed through the first aperture 215, may be electrically connected to the (N−1)th signal patterns 214 of the first circuit substrate 210 through (N−1)th conductive wires 216.

To insulate the (N−1)th conductive wires 216 for electrically connecting the (N−1)th bonding pads 232 to the (N−1)th signal patterns 214, the (N−1)th conductive wires 216 may be encapsulated with an insulation member (e.g., an epoxy resin). Spherical conductive members 217 may be mounted on the (N−1)th signal patterns 214 of the first circuit substrate 210. In example embodiments, the spherical conductive members 217 may include solder balls. The outermost of the spherical conductive members 217 may have a fan-out structure, which means that the outermost spherical conductive members 217 may be partially overlapped with edges of the (N−1)th semiconductor chip 230. Alternatively, the spherical conductive members 217 may not be overlapped with the edges of the (N−1)th semiconductor chip 230.

(N−1)th connection patterns 224 may be provided to the second circuit substrate 220 of the (N−1)th semiconductor package 200. In example embodiments, the (N−1)th connection patterns 224 may function as a terminal of the (N−1)th semiconductor package 200. To form the (N−1)th connection patterns 224, second apertures 225 may be formed through edge portions of the second circuit substrate 220 corresponding to the (N−1)th connection members 240. The second apertures 225 may be filled with the (N−1)th connection patterns 224. The (N−1)th connection members 240, electrically connected to the first circuit substrate 220, may make direct electrical contact with the (N−1)th connection patterns 224 in the second circuit substrate 220. In example embodiments, the (N−1)th connection patterns 224 may include a solder formed by melting a solder paste.

A (N−1)th protection member 250 may be formed between the edge portions of the first and second circuit substrates 210 and 220. The (N−1)th protection member 250 may reduce damage to side faces of the (N−1)th semiconductor chip 230 and the (N−1)th connection members 240. The (N−1)th protection member 250 may retard an interval between the edge portions of the first and second circuit substrates 210 and 220 from being narrowed or widened. The (N−1)th protection member 250 may include an epoxy resin.

The Nth semiconductor package 300 may include a first circuit substrate 310, a second circuit substrate 320, a Nth semiconductor chip 330 and a Nth connection member 340. The first circuit substrate 310 may have a first face 311 and a second face 312 opposite to the first face 311. Nth signal patterns (not shown) for inputting/outputting signal into/from the first circuit substrate 310 may be formed on the first face 311. The first circuit substrate 310 may include a relatively thin printed circuit board (PCB). The second circuit substrate 320 may face the first circuit substrate 310. The second circuit substrate 320 may have a third face 321 and an fourth face 322 opposite to the third face 321. In example embodiments, the third face 321 of the second circuit substrate 320 may face the first face 311 of the first circuit substrate 310. The fourth circuit substrate 320 may include a relatively thin PCB.

The Nth semiconductor chip 330 may be inserted between the first circuit substrate 310 and the second circuit substrate 320. The Nth semiconductor chip 330 may be electrically connected to the second signal patterns to receive the signals from the second signal patterns or output the signals through the second signal patterns. In example embodiments, a (N−1)th adhesive member 342 may be inserted between the first circuit substrate 310 and the Nth semiconductor chip 330. A Nth adhesive member 344 may be inserted between the second circuit substrate 320 and the Nth semiconductor chip 330.

The Nth connection member 340 may be inserted between the first face 311 of the first circuit substrate 310 and the third face 321 of the second circuit substrate 320 to electrically connect the first circuit substrate 310 to the second circuit substrate 320. In example embodiments, the first circuit substrate 310 and the second circuit substrate 320 may absorb external forces to reduce damage to the Nth semiconductor chip 330.

The first circuit substrate 310 and the second circuit substrate 320 may have a first thermal expansion coefficient. The Nth semiconductor chip 330 may have a second thermal expansion coefficient lower than the first thermal expansion coefficient. Because a difference between the first and second coefficients of thermal expansion is compensated with the first and second circuit substrates 310 and 320, the Nth semiconductor chip 330 inserted between the first and second circuit substrates 310 and 320 may not be warped.

The Nth semiconductor chip 330 may have a first area on a plan view. The first and second circuit substrates 310 and 320 may have a second area larger than the first area on a plan view. The Nth semiconductor chip 330 having the first area may be inserted between central portions of the first and second circuit substrates 310 and 320 having the second area. The Nth connection member 340 may be inserted between edge portions of the first and second circuit substrates 310 and 320 that are not overlapped with the Nth semiconductor chip 330.

Nth bonding pads 332, through which the signals are transmitted, may be arranged on the Nth semiconductor chip 330. In example embodiments, the Nth bonding pads 332 may be formed on an upper face of the Nth semiconductor chip 330 facing the first face 311 of the first circuit substrate 310. The Nth bonding pads 332 may be arranged on a central upper face of the Nth semiconductor chip 330.

The first circuit substrate 310 may have a first aperture 315 for exposing the Nth bonding pads 332 of the Nth semiconductor chip 330. The first aperture 315 may have an area suitable for exposing the Nth bonding pads 332 of the Nth semiconductor chip 330. The Nth bonding pads 332 of the Nth semiconductor chip 330 exposed through the first aperture 315 may be electrically connected to the Nth signal patterns of the first circuit substrate 310 through Nth conductive wires 316. To insulate the Nth conductive wires 316 for electrically connecting the Nth bonding pads 332 to the (N−1)th signal patterns, the Nth conductive wires 316 may be encapsulated with an insulation member (e.g., an epoxy resin).

Nth connection patterns 324 may be provided to the second circuit substrate 320 of the Nth semiconductor package 400. To form the Nth connection patterns 324, second apertures 325 may be formed through edge portions of the second circuit substrate 320 corresponding to the Nth connection members 340. The second apertures 325 may be filled with the Nth connection patterns 324. The Nth connection members 340 electrically connected to the first circuit substrate 310 may make direct electrical contact with the Nth connection patterns 324 in the second circuit substrate 320. In example embodiments, the Nth connection patterns 324 may include a solder formed by melting a solder paste.

A Nth protection member 350 may be formed between the edge portions of the first and second circuit substrates 310 and 320. The Nth protection member 350 may reduce damage to side faces of the Nth semiconductor chip 330 and the Nth connection members 340. The Nth protection member 350 may retard or prevent an interval between the edge portions of the first and second circuit substrates 310 and 320 from being narrowed or widened. The Nth protection member 350 may include an epoxy resin.

The Nth semiconductor package 300 may be stacked on the (N−1)th semiconductor package 200. The second circuit substrate 220 of the (N−1)th semiconductor package 200 may face the first circuit substrate 310 of the Nth semiconductor package 300. The (N−1)th connection patterns 224 of the (N−1)th semiconductor package 200 may make contact with the Nth connection patterns 324 of the Nth semiconductor package 300. The (N−1)th and Nth connection patterns 224 and 324 may be melted in an infrared furnace to be electrically connected to each other.

FIG. 11 is a diagram illustrating a method of manufacturing the stacked semiconductor package in FIG. 10. Referring to FIG. 11, to manufacture the stacked semiconductor package 400, the (N−1)th semiconductor package 200 may be formed. The Nth semiconductor package 300 may then be formed. The (N−1)th connection patterns 224 of the (N−1)th semiconductor package 200 may make contact with the Nth connection patterns 324 of the Nth semiconductor package 300. The (N−1)th and Nth connection patterns 224 and 324 may then be melted to complete the stacked semiconductor package 400. According to example embodiments, the circuit substrates may be arranged on both faces of the semiconductor chip so that the semiconductor package may not be warped. The semiconductor chips may be sequentially stacked. The circuit substrates on both faces of the semiconductor chip may reduce damage to the semiconductor chip.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of example embodiments. Accordingly, all such modifications are intended to be included within the scope of example embodiments as defined in the claims. In the claims, means-plus-function clauses are intended to cover the structures described herein as performing the recited function and not only structural equivalents but also equivalent structures. Therefore, it is to be understood that the foregoing is illustrative of example embodiments and is not to be construed as limited to the specific embodiments disclosed, and that modifications to the disclosed embodiments, as well as other embodiments, are intended to be included within the scope of the appended claims. Example embodiments are defined by the following claims, with equivalents of the claims to be included therein.

What is claimed is:

1. A semiconductor package comprising:
a first circuit substrate having an outer face on which signal patterns are arranged;
a second circuit substrate facing an inner face of the first circuit substrate;
a semiconductor chip inserted between the first and second circuit substrates and electrically connected to the signal patterns; and
a connection member electrically connecting the first and second circuit substrates.

2. The semiconductor package of claim 1, wherein the first and second circuit substrates have a first thermal expansion coefficient, and the semiconductor chip has a second thermal expansion coefficient lower than the first thermal expansion coefficient.

3. The semiconductor package of claim 1, wherein the semiconductor chip has a first area, and the first and second circuit substrates have a second area larger than the first area.

4. The semiconductor package of claim 1, wherein the first circuit substrate has a first aperture for exposing bonding pads of the semiconductor chip.

5. The semiconductor package of claim 4, further comprising: conductive wires for electrically connecting the bonding pads to the signal patterns.

6. The semiconductor package of claim 5, further comprising:
an insulation member for covering the conductive wires to insulate the conductive wires.

7. The semiconductor package of claim 1, wherein the first circuit substrate further comprises:
first conductive members electrically connected to the signal patterns.

8. The semiconductor package of claim 7, wherein outermost conductive members are partially arranged at an outside of an edge of the semiconductor chip.

9. The semiconductor package of claim 1, wherein the connection member includes a spherical solder ball for electrically connecting the first and second circuit substrates to each other.

10. The semiconductor package of claim 1, wherein the second circuit substrate has a second aperture corresponding to the connection member.

11. The semiconductor package of claim 10, wherein the second circuit substrate further comprises:
a connection pattern in the second aperture.

12. The semiconductor package of claim 1, further comprising:
a protection member inserted between edge portions of the first and second circuit substrates to protect the semiconductor chip.

13. The semiconductor package of claim 1, further comprising:
adhesive members inserted between the first circuit substrate and the semiconductor chip, and between the semiconductor chip and the second circuit substrate to attach the first and second circuit substrates to the semiconductor chip.

14. A method of manufacturing a semiconductor package, comprising:
preparing a first circuit substrate that has an outer face on which signal patterns are arranged;
preparing a second circuit substrate that faces an inner face of the first circuit substrate;
arranging a connection member between the first and second circuit substrates; and
arranging a semiconductor chip between the first and second circuit substrates to electrically connect the semiconductor chip to the signal patterns.

15. The method of claim 14, wherein preparing the first circuit substrate comprises:
forming a first aperture through the first circuit substrate to expose bonding pads of the semiconductor chip; and
electrically connecting the bonding pads to the signal patterns using conductive wires.

16. The method of claim 15, wherein preparing the first circuit substrate further comprises:
insulating the conductive wires using an insulation member.

17. The method of claim 14, further comprising:
forming a second aperture through the second circuit substrate to expose the connection member;
filling the second aperture with a solder paste; and
melting the solder paste to electrically connect the solder paste to the connection member.

18. The method of claim 14, further comprising:
filling a space defined by the first and second circuit substrates and a side face of the semiconductor chip with a melted resin; and
hardening the melted resin to form a protection member.

19. The method of claim 14, further comprising:
mounting conductive balls on the signal patterns.

20. A stacked semiconductor package comprising:
N (where N is an integer ≧2) semiconductor packages according to claim 1.

21. The stacked semiconductor package of claim 20, wherein the first circuit substrate of the (N−1)th semiconductor package faces the second circuit substrate of the Nth semiconductor package.

22. The stacked semiconductor package of claim 20, wherein the (N−1)th and Nth semiconductor chips have bonding pads electrically connected to the (N−1)th and Nth signal patterns.

23. The stacked semiconductor package of claim 20, further comprising:
an adhesive member inserted between the first circuit substrate of the (N−1)th semiconductor package and the second circuit substrate of the Nth semiconductor package.

24. The stacked semiconductor package of claim 20, further comprising:
the first circuit substrate of the (N−1)th semiconductor package and the second circuit substrate of the Nth semiconductor package including apertures to expose the (N−1)th and Nth connection members, respectively; and
connection patterns formed in the apertures to electrically connect the (N−1)th and Nth connection members to each other.

25. A method of manufacturing a stacked semiconductor package, comprising:
preparing N (where N is an integer ≧2) semiconductor packages according to claim 14; and
stacking the Nth semiconductor package on the (N−1)th semiconductor package to electrically connect the (N−1)th and Nth connection members to each other.

26. The method of claim 25, wherein the first circuit substrate of the (N−1)th semiconductor package faces the second circuit substrate of the Nth semiconductor package.

27. The method of claim 25, wherein the (N−1)th and Nth semiconductor chips have bonding pads electrically connected to the (N−1)th and Nth signal patterns.
